(19) United States
(12) Patent Application Publication
(10) Pub. No.: US 2021/0384367 A1
(43) Pub. Date: Dec. 9, 2021

(54) PHOTOCONDUCTING LAYERED MATERIAL ARRANGEMENT, METHOD OF FABRICATING THE PHOTOCONDUCTING LAYERED MATERIAL ARRANGEMENT, AND USE OF THE PHOTOCONDUCTING LAYERED MATERIAL ARRANGEMENT

(71) Applicant: Technische Universität Darmstadt, Darmstadt (DE)

(72) Inventors: Sascha Preu, Darmstadt (DE); Arthur C. Gossard, Santa Barbara, CA (US); Christopher J. Palmstrom, Santa Barbara, CA (US); Hong Lu, West Covina, CA (US)

(73) Assignee: Technische Universität Darmstadt, Darmstadt (DE)

(21) Appl. No.: 17/408,430

(22) Filed: Aug. 22, 2021

Related U.S. Application Data
(63) Continuation of application No. 16/503,788, filed on Jul. 5, 2019.
Application No. 16/503,788 is a continuation of application No. 15/042,483, filed on Feb. 12, 2016, now abandoned.

(30) Foreign Application Priority Data
Feb. 13, 2015 (DE) 10 2015 102 146.3

(51) Int. Cl. H01L 31/0304; H01L 31/08; H01S 5/30

(52) U.S. Cl. CPC H01L 31/03046; H01L 31/03042; Y02P 70/50; H01S 5/3013; Y02E 10/544; H01L 31/08

(57) ABSTRACT

A photoconducting layered material arrangement for producing or detecting high frequency radiation includes a semiconductor material including an alloy comprised of InGaAs, InGaAsSb, or GaSb, with an admixture of Al, which material is applied to a suitable support substrate in a manner such that the lattices are suitably adjusted, wherewith the semiconductor material comprised of InGaAlAs, InGaAlAsSb, or GaAlSb has a band gap of more than 1 eV, as a consequence of the admixed proportion of Al. The proportion x of Al in the semiconductor material In_{y}Ga_{1-y-x}AlₓAs is between x=0.2 and x=0.35, wherewith the proportion y of In may be between 0.5 and 0.55. The support substrate is InP or GaAs.

### BACKGROUND AND SUMMARY

The present application is a continuation of U.S. application Ser. No. 16/503,788, filed Jul. 5, 2019, which is a continuation of U.S. application Ser. No. 15/042,483, filed Feb. 12, 2016, which claims priority to DE 10 2015 102 146.3, filed Feb. 13, 2015, all of which are incorporated by reference.

The invention relates to a photoconducting layered material arrangement for producing or detecting high frequency radiation.

High frequency radiation with a frequency of more than one gigahertz, particularly terahertz radiation, is increasingly used for spectroscopic applications in the area of medicine and biology, and also for non-destructive materials testing, for wireless communications, and in image-forming imaging methods such as, e.g., [those employed with] body scanners.

Customarily, a photoconducting layered material arrangement is used for detecting high frequency radiation; such an arrangement may be comprised of a semiconductor material with a high dark resistance and a short charge carrier lifetime. For producing high frequency radiation, the semiconductor material may be excited by, e.g., ultrashort laser pulses with a duration of a few femtoseconds. It is also known to excite the photoconducting material by two continuously operated lasers having frequencies with a modulatable difference in the terahertz range (THz). By absorption of the either pulsed or modulated laser light, electron hole pairs are produced in the photoconducting material, and these can be converted into a high frequency alternating current with the aid of a voltage applied from the exterior, which alternating current may be used to generate a high frequency radiation in a suitable antenna device. For detecting high frequency radiation, the electric field of the radiation is mixed with the laser signal in a photoconductor, and is thereby rectified.

Suitable photoconductors have a high dark resistance and a short charge carrier lifetime, in order to enable efficient production and detection of the high frequency radiation.

It is known to fabricate a photoconducting layered material arrangement from gallium arsenide (GaAs). As a result of the semiconductor properties of this alloy, such a photoconductor may be operated with laser light having a wavelength of ca. 800 nanometers. The fabrication of such photoconducting layered material arrangements and the use and operation of laser devices which can be operated with a wavelength of ca. 800 nm are all cost-intensive.

Also, photoconducting layered material arrangements comprised of an indium gallium arsenide semiconductor material (InGaAs) are known which can be excited and operated with laser light having a wavelength of ca. 1550 nanometers. Although laser devices with such a wavelength can be economically employed and operated, the semiconductor material InGaAs has an appreciably higher conductivity, resulting in a comparably high dark current and low sending power, and increased noise when used in detector mode.

Accordingly, an underlying problem was to devise a photoconducting layered material arrangement for producing or detecting high frequency radiation, such that said arrangement can be manufactured economically and can be utilized efficiently and economically for producing or detecting high frequency radiation, particularly THz radiation.

### DETAILED DESCRIPTION

According to an aspect of the invention in that a semiconductor material comprised of an alloy of InGaAs, InGaAsSb, or GaSb with a content of Al is disposed on a suitable support substrate, wherewith the semiconductor material comprised of InGaAs, InGaAsSb, or GaSb has a band gap of more than 1 electron volt (>1 eV). The alloy InGaAs (indium gallium arsenide) is an alloy associated with III-V compound semiconductors, and has found use in optoelectronics. The mixture ratio of indium (In) and gallium (Ga) may be chosen somewhat arbitrarily—the band gap of the alloy will vary in the range between 0.34 and 1.42 eV depending on the mixture ratio. Ordinary commercially available indium gallium arsenide with a mixture ratio of x=0.47 (usually denoted by “In_{0.53}Ga_{0.47}As”) is commonly applied by means of known crystal growing methods onto a supporting substrate with a maximally similar lattice constant, or with the same lattice constant. The band gap of In_{0.53}Ga_{0.47}As is 0.75 eV. The compound semiconductor gallium antimonide (GaSb), also usable according to the invention, has comparable properties and has a band gap of 0.72 eV. A larger band gap range can be accessed by admixture of indium and aluminum (InAlGaSb).

It has been found that admixture of a proportion of aluminum (Al) can advantageously influence the band gap of ordinary commercially available indium gallium arsenide, e.g. can increase the band gap. In this way, one can retain advantageous properties such as, e.g., a lower dark current and a short charge carrier lifetime, when the material is used as an active component in a photoconductor [material], and by increasing the band gap to more than 1 eV one can achieve operation of such a photoconductor with a laser light having wavelength between 950 and 1100 nanometers. An inventive photoconductor can thus be operated, e.g., with economically advantageous Yb fiber lasers or with laser diodes (also commonly commercially available and economical) having a wavelength of 980 or 1064 nanometers [respectively].

It has been found that when a proportion of Al is admixed in, replacing a corresponding proportion of Ga in the semiconductor material, nearly zero change in the lattice constant of the semiconductor material is experienced, which makes it appreciably easier to dispose the material coating on the support substrate. The semiconductor material gallium bismuth arsenide (GaBiAs), which is also well known in practice and which has bismuth (Bi) as an admixture component, which bismuth replaces a corresponding proportion of gallium atoms, can only be fabricated under stressing. Also, bismuth cannot be used in molecular beam epitaxial deposition equipment, and therefore it is difficult and costly to fabricate layers comprised of GaBiAs.

It has further been found that one can provide an advantageous band gap between ca. 1.0 and 1.2 eV (or higher) for use in semiconductors if the proportion x of Al in the semiconductor material In_{y}Ga_{1-y-x}AlₓAs is between x=0.2 and x=0.35, wherewith the proportion y of In may be between 0.5 and 0.55. It is also possible to employ a smaller or larger proportion of In. The band gap should not be appreciably below 1 eV, in order to achieve a sufficiently high dark resistance. In order to enable efficient operation of such a photoconductor with laser light having a wavelength of ca. 1030 nanometers, the band gap should not be smaller than 1.2 eV.

Based on the advantageous and substantially equal lattice structures, it is advantageously provided [according to the invention] that the support substrate comprises indium phosphide (InP) or gallium arsenide (GaAs). These support substrates may also be used, e.g., for growing of crystals of indium gallium arsenide, and can be obtained inexpensively from ordinary commercial sources.

According to an advantageous embodiment of the inventive concept, the semiconductor material has inclusions of rare earth (V) compounds. Preferably the inclusions contain [sic] erbium arsenide (ErAs) or erbium antimonide (ErSb). A benefit of having inclusions of rare earth (V) compounds is that the desired short charge carrier lifetimes can be further shortened. It has been found, with use of the rare earth (V) compounds ErAs and ErSb, that it is easy to bring about the inclusions of these rare earth (V) compounds, and that this is unaccompanied by any adverse effects on the growth of the semiconductor material, and further that useful defects are produced near the conduction band of the semiconductor material, and the lifetime of the electron-hole pairs produced is effectively reduced. The Fermi energy of the defects produced by the inclusions is farther from the conduction band of the semiconductor material than in indium gallium arsenide, due to the admixed proportion of Al, which also results in an advantageous reduction of the dark conduction capability of the semiconductor material.

Regarding the use of the photoconducting layered material arrangement in THz radiation components such as e.g., photo-mixer devices or THz radiation producers, it is advantageous that the photoconducting layered material arrangement has at least two material layers comprised of the semiconductor material InGaAlAs, InGaAlAsSb, or GaAlSb, with different respective Al contents. It has been found that a combination of a material layer comprised of an inventive semiconductor material with an admixture of Al, on the one hand, with an alloy not having an admixture of Al, on the other hand, or with a semiconductor material having a small admixture of Al, is well suited for use in a photoconductor. The alloy, or the semiconductor material with a small admixture of Al, may correspond with the semiconductor material which is employed which has an [appreciable] admixture of Al. Combinations of materials layers are also possible which rely on different alloys, however.

In such a double-layer structure, the material layer comprised of the semiconductor material with the admixture of Al preferably has a layer thickness of ca. 1-10 nm, whereas the material layer without the admixture of Al or with only a small amount of Al admixture has a somewhat greater thickness of more than 7 nm to typically ca. 50 nm. The material layer comprised of the semiconductor material with the admixture of Al advantageously has inclusions of rare earth (V) compounds which serve to capture charge carriers and generate a high resistance. A material layer with a low Al admixture serves for photoabsorption. The photoconducting active region of a photoconductor advantageously has a larger number of such superposed double layers, wherewith this layered material arrangement will then have an overall thickness of ca. 300-500 nm or more.

Preferably, at least material layers are provided which are comprised of the semiconductor material InGaAlAs, InGaAlAsSb, or GaAlSb, and a material layer without inclusions of rare earth (V) compounds is disposed between two neighboring material layers with inclusions of rare earth (V) compounds. The material layers with inclusions, in which the charge carrier lifetime is short as a result of the defects that are produced, serve as active photoconducting material layers that are separated by a separating layer comprised of a material layer without inclusions. By an arrangement with a plurality of active layers separated by respective suitable separating layers, one can improve the efficiency and power of the photoconducting layered material arrangement for producing and for detecting high frequency radiation.

It has been found that it is advantageous for the material layer without inclusions of rare earth (V) compounds which is disposed between two neighboring material layers with inclusions of rare earth (V) compounds to have a layer thickness of less than 200 nm, preferably less than 30 nm.

According to an advantageous embodiment of the inventive concept, the semiconductor material has additional doping. In the semiconductor material InGaAlAs, a p-conducting doping is advantageous, in order to at least partially compensate for the n-conducting characteristics of the semiconductor material. In the semiconductor material GaAlSb or InGaAlAsSb, an n-conducting doping may be advantageous.

For the p-doping, one may use, e.g., beryllium (Be) or carbon (C). For the n-doping, one may use, e.g., silicon (Si) in the case of layers containing InAlGaAs, or tellurium (Te) in the case of layers containing GaSb.

Advantageously, the material layers with inclusions of rare earth (V) compounds may have strong doping, and the material layers without inclusions of rare earth (V) compounds may have weak doping or no doping. Compared to strong doping, weak doping has additional inclusions of fewer than 1×10⁻¹⁷ dopant atoms (foreign atoms) per cm³. As a result of the change in the intensity of doping, corresponding to the inclusions of rare earth (V) compounds, the sensitivity and efficiency of the photoconducting layered material arrangement may be additionally improved.

The invention further relates to a method of fabricating a photoconducting layered material arrangement. According to the invention, it is provided that a semiconductor material comprised of an alloy of InGaAs or InGaAsSb with an admixture of Al is applied to a support substrate with an appropriate lattice. The support substrate, comprised of e.g. InP or GaAs, advantageously has a suitable lattice structure, by means of which the lattice structure of the lattice structure of the thereon applied (or grown) semiconductor material is favorably influenced (and/or produced). The adjustment of the lattice of the GaSb alloy with the admixture of Al may be brought about by insertion [sic] of a stress-reducing buffer layer.

Molecular beam epitaxy is a method of applying the semiconductor material to the support substrate, which method has proved advantageous in experiments. It is also possible, particularly in alloys such as GaAs or InGaAs, to employ known low temperature growth methods.

To improve the photoconducting properties, it is proposed that rare earth (V) compounds be added to the semiconductor material. The photoconducting layered material arrangement may have a plurality of successively superposed material layers having different properties, which layers are successively applied on the support substrate. The individual material layers may each have dopant atoms added to them prior to the time that the subsequent material layer is applied to the given material layer.

The invention further relates to use of a photoconducting layered material arrangement with the above-described properties, in a photo-mixer device which is operated with laser devices having a laser light wavelength between 950 and 1100 nm. Through the inventively provided properties of the photoconducting layered material arrangement it is possible to operate photoconducting components such as, e.g., a photo-mixer device with laser devices which are inexpensive to acquire and to operate. Particularly well suited are fiber lasers such as, e.g., Yb-doped or Yb—Er-co-doped fiber lasers or laser diodes [lit., “laser iodes”] which emit laser light with a wavelength of 980 or 1064 nm, and are commonly commercially available.

1. Use of a photoconducting layered material for producing or detecting high frequency radiation in a THz radiation component which is operated with laser devices having a laser light wavelength between 950 and 1100 nm, wherein, in the photoconducting layered material, a semiconductor material comprised of an alloy comprised of InGaAs, InGaAsSb, or GaSb, with an admixture of Al, is disposed on a suitable support substrate, wherewith the semiconductor material comprised of InGaAlAs, InGaAlAsSb, or GaAlSb has a band gap of more than 1 eV, as a consequence of the admixed proportion of Al, wherein the proportion x of Al in the semiconductor material In_{y}Ga_{1-y-x}AlₓAs is between x=0.2 and x=0.35, wherewith the proportion y of In may be between 0.5 and 0.55, wherein the semiconductor material has inclusions of rare earth (V) compounds, and wherein the photoconducting layered material arrangement has at least two material layers comprised of the semiconductor material InGaAlAs, InGaAlAsSb, or GaAlSb, with different contents of Al.

2. Use of the photoconducting layered material arrangement according to claim 1, wherein the support substrate is InP or GaAs.

3. Use of the photoconducting layered material arrangement according to claim 1, wherein the inclusions contain ErAs or ErSb.

4. Use of the photoconducting layered material arrangement according to claim 1, wherein the layered material arrangement has a material layer comprised of an inventive semiconductor material with an admixture of Al, and an adjoining material layer comprised of an alloy without an admixture of Al or comprised of a semiconductor material with a low admixture of Al.

5. Use of the photoconducting layered material arrangement according to claim 4, wherein a layered material arrangement has an arrangement of a plurality of superposed material layers wherein a certain layer is comprised of an inventive semiconductor material with an admixture of Al and the adjoining layer is comprised of an alloy without an admixture of Al or an alloy with a small admixture of Al, and these structures are stacked above each other, with an overall thickness of more than 300 nm.

6. Use of the photoconducting layered material arrangement according to claim 1, wherein the photoconducting layered material arrangement has at least three material layers comprised of the semiconductor material InGaAlAs, InGaAlAsSb, or GaAlSb, wherein a material layer without inclusions of rare earth (V) compounds is disposed between two neighboring material layers with inclusions of rare earth (V) compounds.

7. Use of the photoconducting layered material arrangement according to claim 6, wherein the material layer without inclusions of rare earth (V) compounds which is disposed between two neighboring material layers with inclusions of rare earth (V) compounds has a layer thickness of less than 200 nm.

8. Use of the photoconducting layered material arrangement according to claim 1, wherein the semiconductor material has an at least partially compensating doping.

9. Use of the photoconducting layered material arrangement according to claim 6, wherein the semiconductor material has an ate least partially compensating doping, and, wherein the material layers with inclusions of rare earth (V) compounds have strong doping, and the material layer without inclusions of rare earth (V) compounds has weak doping or no doping.

10. Use of the photoconducting layered material arrangement according to claim 1, wherein the THz radiation component is one of a photo-mixer device or a THz radiation producer.

11. A THz radiation component configured to use a photoconducting layered material for producing or detecting high frequency radiation and which is operated with laser devices having a laser light wavelength between 950 and 1100 nm, wherein, in the photoconducting layered material, a semiconductor material comprised of an alloy comprised of InGaAs, InGaAsSb, or GaSb, with an admixture of Al, is disposed on a suitable support substrate, wherewith the semiconductor material comprised of InGaAlAs, InGaAlAsSb, or GaAlSb has a band gap of more than 1 eV, as a consequence of the admixed proportion of Al, wherein the proportion x of Al in the semiconductor material In_{y}Ga_{1-y-x}AlₓAs is between x=0.2 and x=0.35, wherewith the proportion y of In may be between 0.5 and 0.55, wherein the semiconductor material has inclusions of rare earth (V) compounds, and wherein the photoconducting layered material has at least two material layers comprised of the semiconductor material InGaAlAs, InGaAlAsSb, or GaAlSb, with different contents of Al.

12. The THz radiation component according to claim 11, wherein the support substrate is InP or GaAs.

13. The THz radiation component according to claim 11, wherein the inclusions contain ErAs or ErSb.

14. The THz radiation component according to claim 11, wherein the layered material arrangement has a material layer comprised of an inventive semiconductor material with an admixture of Al, and an adjoining material layer comprised of an alloy without an admixture of Al or comprised of a semiconductor material with a low admixture of Al.

15. The THz radiation component according to claim 14, wherein a layered material arrangement has an arrangement of a plurality of superposed material layers wherein a certain layer is comprised of an inventive semiconductor material with an admixture of Al and the adjoining layer is comprised of an alloy without an admixture of Al or an alloy with a small admixture of Al, and these structures are stacked above each other, with an overall thickness of more than 300 nm.

16. The THz radiation component according to claim 11, wherein the photoconducting layered material arrangement has at least three material layers comprised of the semiconductor material InGaAlAs, InGaAlAsSb, or GaAlSb, wherein a material layer without inclusions of rare earth (V) compounds is disposed between two neighboring material layers with inclusions of rare earth (V) compounds.

17. The THz radiation component according to claim 16, wherein the material layer without inclusions of rare earth (V) compounds which is disposed between two neighboring material layers with inclusions of rare earth (V) compounds has a layer thickness of less than 200 nm.

18. The THz radiation component according to claim 16, wherein the semiconductor material has an at least partially compensating doping, and, wherein the material layers with inclusions of rare earth (V) compounds have strong doping, and the material layer without inclusions of rare earth (V) compounds has weak doping or no doping.

19. The THz radiation component according to claim 11, wherein the semiconductor material has an at least partially compensating doping.

20. The THz radiation component according to claim 11, wherein the THz radiation component is one of a photo-mixer device or a THz radiation producer.
